(19) United States
(12) Patent Application Publication
(10) Pub. No.: US 2026/0156994 A1
(43) Pub. Date: Jun. 4, 2026

(54) LIGHT EMITTING MODULE

(71) Applicant: SEOUL VIOSYS CO., LTD., Ansan-si (KR)

(72) Inventor: Hongjae YOO, Ansan-si (KR)

(73) Assignee: SEOUL VIOSYS CO., LTD., Ansan-si (KR)

(21) Appl. No.: 19/390,975

(22) Filed: Nov. 17, 2025

Related U.S. Application Data
(60) Provisional application No. 63/722,171, filed on Nov. 19, 2024.
(60) Provisional application No. 63/780,595, filed on Mar. 31, 2025.
(60) Provisional application No. 63/794,505, filed on Apr. 25, 2025.

(51) Int. Cl. H10H 29/14; H10H 20/812; H10H 20/813; H10H 29/80

(52) U.S. Cl. CPC H10H 29/142; H10H 20/812; H10H 20/8131; H10H 29/8321

(57) ABSTRACT

The present invention discloses a light emitting module including a substrate and a plurality of light-emitting regions disposed on one surface of the substrate, in which at least one of the plurality of light-emitting regions includes a non light-emitting active layer disposed so as to deviate from a current path when power is applied.

### TECHNICAL FIELD

The present invention relates to a light emitting module including light-emitting regions.

### BACKGROUND ART

A light emitting diode (LED) is one of light emitting devices that emit light when current is applied. Recently, the light emitting diode has been widely used in various technical fields such as display apparatuses, vehicle lamps, and general lighting. Moreover, the light emitting diode has advantages of long life, low power consumption, and fast response speed. By taking full advantage of these advantages, it has been rapidly replacing a conventional light source. For example, a display apparatus using the light emitting diode may be obtained by forming structures of individually grown red R, green G, and blue B light emitting diodes (LEDs) on a final substrate.

The display apparatus generally produces various colors using a mixture of blue, green, and red. The display apparatus includes a plurality of pixels to implement various images, and each of the pixels has blue, green, and red sub-pixels. The color of a specific pixel is determined by colors of these sub-pixels, and an image is implemented by the combination of these pixels.

### DISCLOSURE

### Technical Problem

The present invention may provide a light emitting module that can improve productivity by a simple process.

The present invention may provide a light emitting module that can prevent damage or device peeling due to heat generation.

The present invention may provide a light emitting module that can finely adjust luminous intensity and a wavelength between light-emitting regions.

The present invention may provide a light emitting module that can increase an amount of light by securing a large light-emitting area.

The present invention may provide a light emitting module that can prevent a PL (Photoluminescence) phenomenon in which a light-emitting region is excited by light emitted from another light-emitting region.

The present invention may provide a light emitting module that can increase light emitting efficiency by reducing loss of power applied thereto.

The present invention may provide a light emitting module capable of firmly coupling layers that form a light-emitting region.

The present invention may provide a light emitting module with improved performance and reliability and high light extraction efficiency.

### Technical Solution

A light emitting module according to an embodiment of the present invention includes a substrate and a plurality of light-emitting regions disposed on one surface of the substrate, and at least one of the plurality of light-emitting regions includes a non light-emitting active layer disposed so as to deviate from a current path when power is applied.

In an embodiment, the non light-emitting active layer may be provided in a plurality.

In an embodiment, each of the plurality of light-emitting regions may include an active layer that emits light when power is applied.

In an embodiment, one of the plurality of light-emitting regions may be a first light-emitting region including a first non light-emitting active layer, a second non light-emitting active layer disposed over the first non light-emitting active layer, and a first active layer disposed over the second non light-emitting active layer and emitting first light when current is applied.

In an embodiment, another of the plurality of light-emitting regions may be a second light-emitting region including a first non light-emitting active layer and a second active layer disposed over the first non light-emitting active layer and emitting second light when current is applied.

In an embodiment, another of the plurality of light-emitting regions may be a third light-emitting region including a third active layer disposed over the substrate and emitting third light when current is applied.

In an embodiment, heights from an upper surface of the substrate to the first through third active layers may be different from one another.

In an embodiment, first through third light emitted from the first through third active layers may have peak wavelengths different from one another.

The first through third light-emitting regions includes a second electrode disposed over the first through third active layers, respectively,

In an embodiment, heights from the upper surface of the substrate to the second electrode for each of the first through third light-emitting regions may be different from one another.

A light emitting module according to another embodiment of the present invention includes a substrate and a plurality of light-emitting regions disposed on one surface of the substrate, in which the plurality of light-emitting regions may includes a plurality of active layers, and power applied to the plurality of light-emitting regions may be independently controlled.

In an embodiment, numbers of the active layers included in each of the plurality of light-emitting regions may be the same.

In an embodiment, a dominant wavelength of light emitted from the light-emitting region may be varied depending on a current applied to the light-emitting region.

In an embodiment, the light-emitting region may include a first active layer disposed on a first conductivity type semiconductor layer, a first carrier barrier layer disposed on the first active layer, a second active layer disposed on the first carrier barrier layer, a second carrier barrier layer disposed on the second active layer, a third active layer disposed on the second carrier barrier layer, and a second conductivity type semiconductor layer disposed on the third active layer.

In an embodiment, the first through third active layers may emit light having a peak wavelength different from one another, respectively.

In an embodiment, a band gap may decrease from the first active layer to the third active layer.

In an embodiment, a thickness of a barrier layer of the third active layer may be larger than those of barrier layers of the first active layer and the second active layer.

In an embodiment, the first through third active layers include a multi quantum well structure in which barrier layers and well layers are sequentially stacked, and a number of pairs of the multi quantum well structure of the first active layer may be the greatest.

In an embodiment, doping concentrations of the first and second carrier barrier layers may be lower than that of the first conductivity type semiconductor layer.

In an embodiment, the first through third active layers include a multi quantum well structure in which barrier layers and well layers are sequentially stacked, and the first and second carrier barrier layers may have a band gap higher than that of an adjacent barrier layer.

According to another embodiment of the present invention, a light emitting module includes a substrate and a plurality of light-emitting regions disposed on one surface of the substrate, a first common electrode commonly connected to the plurality of light-emitting regions, and a plurality of second individual electrodes connected to the plurality of light-emitting regions, respectively, in which at least one of the plurality of light-emitting regions includes a plurality of active layers, and power applied to the plurality of light-emitting regions may be independently controlled.

### Advantageous Effect

The present invention may provide a light emitting module that can improve productivity by a simple process.

The present invention may provide a light emitting module that can prevent damage or device peeling due to heat generation.

The present invention may provide a light emitting module that can finely adjust luminous intensity and a wavelength between light-emitting regions.

The present invention may provide a light emitting module that can increase an amount of light by securing a large light-emitting area.

The present invention may provide a light emitting module that can increase light emitting efficiency by reducing loss of power applied thereto.

The present invention may provide a light emitting module that can prevent a PL (Photoluminescence) phenomenon in which a light-emitting region is excited by light emitted from another light-emitting region.

The present invention may provide a light emitting module capable of firmly coupling layers that form a light-emitting region.

The present invention may provide a light emitting module with improved performance and reliability and high light extraction efficiency.

### BRIEF DESCRIPTION OF DRAWING

FIG. 1 is a cross-sectional view showing a light emitting module according to a first embodiment of the present invention.

FIG. 2 is a plan view showing the light emitting module of FIG. 1.

FIG. 3 is a modified example of FIG. 2.

FIG. 4 is a cross-sectional view showing a light emitting module according to a second embodiment of the present invention.

FIG. 5 is a cross-sectional view showing a light emitting module according to a third embodiment of the present invention.

FIG. 6 is a cross-sectional view showing a light emitting module according to a fourth embodiment of the present invention.

FIG. 7 is a cross-sectional view showing a light emitting module according to a fifth embodiment of the present invention.

### DETAILED DESCRIPTION OF THE ILLUSTRATED EMBODIMENTS

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

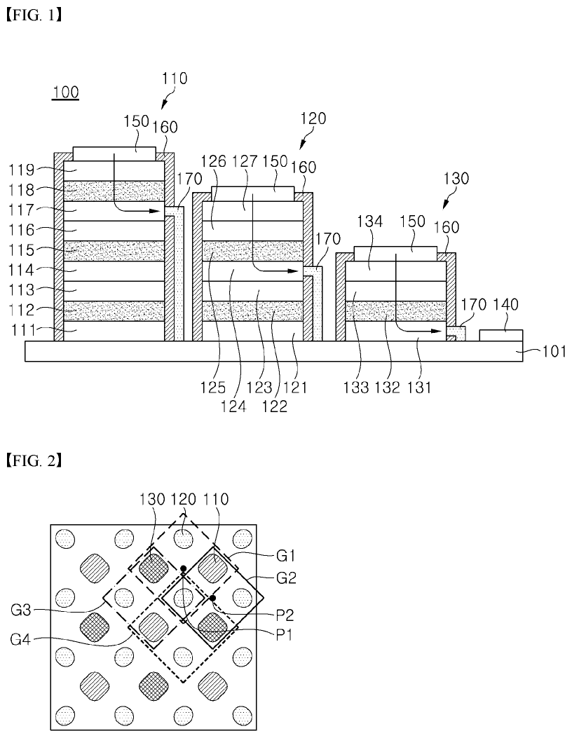

Hereinafter, a light emitting module of the present invention will be described in detail with reference to accompanying drawings. FIG. 1 is a drawing showing a light emitting module 100 according to a first embodiment of the present invention.

Referring to FIG. 1, the light emitting module 100 according to the first embodiment may include a substrate 101 and a plurality of light-emitting regions 110, 120, and 130 disposed on one surface of the substrate 101. For example, the light emitting module 110 may include three first through third light-emitting regions 110, 120, and 130 as shown in FIG. 1.

The substrate 101 is configured to support the light-emitting regions 110, 120, and 130, and various configurations are possible. For example, the substrate 101 may be a growth substrate capable of growing a semiconductor layer. For example, it may include a heterogeneous substrate such as a sapphire substrate, a gallium arsenide substrate, a silicon substrate, a silicon carbide substrate, or a spinel substrate, and in addition, may include a homogeneous substrate such as a gallium nitride substrate, an aluminum nitride substrate, or the like.

As another example, the substrate 101 may be a circuit board, a light-transmitting substrate, a glass substrate, a TFT substrate, a polymer substrate, a flexible substrate, a polyimide substrate, or the like.

In addition, the substrate 101 may be formed with an area larger than that of the light-emitting regions 110, 120, and 130.

In addition, the substrate 101 may be a light-transmitting substrate so as to transmit light. Alternatively, the substrate 101 may include an insulating material. However, the present invention is not limited thereto, and the substrate 101 may be formed to be translucent or partially transparent so as to transmit only light of a specific wavelength or only a portion of light of a specific wavelength.

The plurality of light-emitting regions 110, 120, and 130 are electrically isolated from one another, and may be independently driven and controlled. The plurality of light-emitting regions 110, 120, and 130 may be spaced apart from one another on one surface of the substrate 101.

Each of the plurality of light-emitting regions 110, 120, and 130 may include different numbers of active layers from one another. That is, the numbers of active layers provided in the first through third light-emitting regions 110, 120, and 130 may be different.

At least one of the first through third light-emitting regions 110, 120, and 130 may include a plurality of active layers. A plurality of active layers included in one light-emitting region 110, 120, or 130 may be vertically stacked. At least one of the active layers included in the light-emitting regions 110, 120, and 130 may emit light, respectively, when power is applied.

Remaining active layers of the plurality of active layers included in the light-emitting regions 110, 120, and 130 excluding at least one may be non light-emitting active layers that do not emit light. The non light-emitting active layer may refer to an active layer that is disposed so as to deviate from a current path when power is applied to the light-emitting region 110, 120, and 130 and does not emit light. That is, at least one of the first through third light-emitting regions 110, 120, and 130 may include a non light-emitting active layer disposed so as to deviate from the current path when power is applied.

The non light-emitting active layer is a layer that does not emit light even when power is applied to the light-emitting regions 110, 120, and 130, and may be disposed below the light-emitting regions 110, 120, and 130. At least one of the first through third light-emitting regions 110, 120, and 130 may be configured to include only one active layer, and may not include a non light-emitting active layer.

Numbers of non light-emitting active layers provided in each of the first through third light-emitting regions 110, 120, and 130 may be different from one another.

For example, the first light-emitting region 110 may include three active layers, and two of the three active layers may be non light-emitting active layers. A remaining one active layer is a layer that emits light when power is applied to the first light-emitting region 110 and may be disposed over the two non light-emitting active layers.

The second light-emitting region 120 may include two active layers, and one of the two active layers may be a non light-emitting active layer. A remaining one active layer is a layer that emits light when power is applied to the second light-emitting region 120 and may be disposed over the one non light-emitting active layer.

The third light-emitting region 130 may include one active layer, and may be a layer that emits light when power is applied. That is, the third light-emitting region 130 may not include a non light-emitting active layer.

This is exemplary, and the numbers of non light-emitting active layers included in each of the first light-emitting region 110 through the third light-emitting region 130 may vary. For example, FIG. 1 exemplarily illustrates that the first light-emitting region 110 includes two non light-emitting active layers, the second light-emitting region 120 includes one non light-emitting active layer, and the third light-emitting region 130 does not include a non light-emitting active layer, but the present invention is not limited thereto.

In detail, the first light-emitting region 110 may include a first conductivity type semiconductor layer 111 disposed on one surface of the substrate 101, a first non light-emitting active layer 112 disposed over the first conductivity type semiconductor layer 111, a second non light-emitting active layer 115 disposed over the first non light-emitting active layer 112, and a first active layer 118 disposed over the second non light-emitting active layer 115.

The first non light-emitting active layer 112 and the second non light-emitting active layer 115 may be active layers that do not emit light when power is applied to the first light-emitting region 110, and the first active layer 118 may be an active layer that emits first light when power is applied to the first light-emitting region 110.

The first conductivity type semiconductor layer 111 may be a semiconductor layer grown on one surface of the substrate 101, and may include a phosphide or nitride semiconductor such as (Al, Ga, In)P or (Al, Ga, In)N. In addition, the first conductivity type semiconductor layer 111 may be doped as an n-type by including one or more impurities such as Si, C, Ge, Sn, Te, Pb, or others. The present invention is not limited thereto, and as another example, the first conductivity type semiconductor layer 111 may be doped with an opposite conductivity type, including a p-type dopant. In addition, the first conductivity type semiconductor layer 111 may be formed as a single layer or multiple layers.

A buffer layer may be further disposed between the first conductivity type semiconductor layer 111 and the substrate 101.

The first non light-emitting active layer 112 is an active layer disposed on the first conductivity type semiconductor layer 111, may include a phosphide or nitride semiconductor such as (Al, Ga, In)P or (Al, Ga, In)N, and may be grown on the first conductivity type semiconductor layer 111 using a technique such as MOCVD, MBE, HVPE, or the like.

In addition, the first non light-emitting active layer 112 may include a quantum well structure (QW) including at least two barrier layers and at least one well layer, and moreover, may include a multi quantum well structure (MQW) including a plurality of barrier layers and a plurality of well layers. A wavelength of light emitted from the first non light-emitting active layer 112 may be adjusted by controlling a composition ratio of materials forming the well layer. In this case, the well layers may include a same element in common, for example, In.

The first light-emitting region 110 may further include a pre-strain layer disposed between the first non light-emitting active layer 112 and the first conductivity type semiconductor layer 111. The pre-modification layer may include a single layer or a plurality of sub-layers. At least one of the plurality of sub-layers may be a Si doped layer. In addition, one of the plurality of sub-layers may be a superlattice layer periodically stacked with layers of different compositions. The superlattice layer may include InGaN/GaN. In addition, the pre-strain layer may include a layer including In. In addition, the pre-strain layer may include a region where an In composition decreases in concentration as it is farther from the substrate 101.

The second non light-emitting active layer 115 is an active layer disposed on the first non light-emitting semiconductor layer 112, may include a phosphide or nitride semiconductor such as (Al, Ga, In)P or (Al, Ga, In)N, and may be grown on the first non light-emitting semiconductor layer 112 using a technique such as MOCVD, MBE, HVPE, or the like.

In addition, the second non light-emitting active layer 115 may include a quantum well structure (QW) including at least two barrier layers and at least one well layer, and moreover, may include a multi quantum well structure (MQW) including a plurality of barrier layers and a plurality of well layers. A wavelength of light emitted from the second non light-emitting active layer 115 may be adjusted by controlling a composition ratio of materials forming the well layer. In this case, the well layers may include a same element in common, for example, In.

The first active layer 118 is an active layer disposed on the second non-light emitting semiconductor layer 115, may include a phosphide or nitride semiconductor such as (Al, Ga, In)P or (Al, Ga, In)N, and may be grown on the second non-light emitting semiconductor layer 115 using a technique such as MOCVD, MBE, HVPE, or the like.

In addition, the first active layer 118 may include a quantum well structure (QW) including at least two barrier layers and at least one well layer, and moreover, may include a multi quantum well structure (MQW) including a plurality of barrier layers and a plurality of well layers. A wavelength of light emitted from the first active layer 118 may be adjusted by controlling a composition ratio of materials forming the well layer. In this case, the well layers may include a same element in common, for example, In.

A number of pairs of the barrier layers and the well layers of the first non light-emitting active layer 112 may be different from that of pairs of the second non light-emitting active layer 115 or the first active layer 118. The number of pairs of the barrier layers and the well layers of the second non light-emitting active layer 115 may be different from that of pairs of the first non light-emitting active layer 112 or the first active layer 118. The number of pairs of the barrier layers and the well layers of the first active layer 118 may be different from that of pairs of the first non light-emitting active layer 112 or the second non light-emitting active layer 115.

An indium content of the first non light-emitting active layer 112 may be different from that of the second non light-emitting active layer 115 or the first active layer 118. The indium content of the second non light-emitting active layer 115 may be different from that of the first non light-emitting active layer 112 or the first active layer 118. The indium content of the first active layer 118 may be different from that of the first non light-emitting active layer 112 or the second non light-emitting active layer 115.

The first light-emitting region 110 may further include a first connection region 114 disposed between the first non light-emitting active layer 112 and the second non light-emitting active layer 115.

The first connection region 114 may be a conductive semiconductor layer doped with first and second conductive dopants. A doping concentration of the first connection region 114 may be higher than those of the first non light-emitting active layer 112 and the second non light-emitting active layer 115.

A lower portion of the first connection region 114 may be a layer doped with a first conductive dopant, and an upper portion of the first connection region 114 may be a layer doped with a second conductive dopant. Conversely, the lower portion of the first connection region 114 may be a layer doped with a second conductive dopant, and the upper portion of the first connection region 114 may be a layer doped with a first conductive dopant.

The first connection region 114 may be a nitride semiconductor layer, and may include 40% or more (at % or wt %) of nitride. The first connection region 114 may create a robust bond between the upper and lower semiconductor layers due to the stable characteristics of the nitride material.

The first light-emitting region 110 may further include a second connection region 117 disposed between the second non light-emitting active layer 115 and the first active layer 118.

The second connection region 117 may be a conductive semiconductor layer doped with first and second conductive dopants. A doping concentration of the second connection region 117 may be higher than those of the second non light-emitting active layer 115 and the first active layer 118.

A lower portion of the second connection region 117 may be a layer doped with a first conductive dopant, and an upper portion of the second connection region 117 may be a layer doped with a second conductive dopant. Conversely, the lower portion of the second connection region 117 may be a layer doped with a second conductive dopant, and the upper portion of the second connection region 117 may be a layer doped with a first conductive dopant.

The second connection region 117 may be a nitride semiconductor layer, and may include 40% or more (at % or wt %) of nitride. The second connection region 117 may make a bond between the upper and lower semiconductor layers robust by using a nitride material having stable characteristics.

A thickness of the second connection region 117 may be different from that of the first connection region 114. For example, the thickness of the second connection region 117 may be smaller than that of the first connection region 114.

In addition, dopant concentrations of the first connection region 114 and the second connection region 117 may be different from each other. The first connection region 114 and the second connection region 117 may include a same group V material as that of the active layers 112, 115, and 118.

In addition, the first light-emitting region 110 may further include a first carrier barrier layer 113 disposed between the first non light-emitting active layer 112 and the second non light-emitting active layer 115, and a second carrier barrier layer 116 disposed between the second non light-emitting active layer 115 and the first active layer 118.

The first carrier barrier layer 113 may be disposed between the first non light-emitting active layer 112 and the first connection region 114.

The first carrier barrier layer 113 is a layer for controlling and blocking a movement of carriers distributed within the first non light-emitting active layer 112 and the second non light-emitting active layer 115, and various configurations are possible. The first non light-emitting active layer 112 and the second non light-emitting active layer 115 may be separated by the first carrier barrier layer 113.

The first carrier barrier layer 113 may have a band gap energy greater than the band gap energies of the barrier layers of the first non light-emitting active layer 112, the second non light-emitting active layer 115, and the first active layer 118. A thickness of the first carrier barrier layer 113 may be within a range of 5 nm to 500 nm.

The first carrier barrier layer 113 may be a layer including InₓAl_{y}Ga_{(1-x-y)}N (0≤x≤1, 0≤y≤1).

In addition, the first carrier barrier layer 113 may be doped at a concentration lower than that of the first conductivity type semiconductor layer 111 or may not be doped.

The second carrier barrier layer 116 may be disposed between the second non light-emitting active layer 115 and the second connection region 117.

The second carrier barrier layer 116 is a layer for controlling and blocking a movement of carriers distributed within the second non light-emitting active layer 115 and the first active layer 118, and various configurations are possible. The second non light-emitting active layer 115 and the first active layer 118 may be separated by the second carrier barrier layer 116.

The second carrier barrier layer 116 may have a band gap energy greater than the band gap energies of the barrier layers of the first non light-emitting active layer 112, the second non light-emitting active layer 115, and the first active layer 118. A thickness of the second carrier barrier layer 116 may be within the range of 5 nm to 500 nm.

The second carrier barrier layer 116 may be a layer including InₓAl_{y}Ga_{(1-x-y)N (}0≤x≤1, 0≤y≤1).

In addition, the second carrier barrier layer 116 may be doped at a concentration lower than that of the first conductivity type semiconductor layer 111 or may not be doped.

The thickness or band gap energy of the second carrier barrier layer 116 may be same as or different from the thickness or band gap energy of the first carrier barrier layer 113.

The first and second carrier barrier layers 113 and 116 may be disposed only between the active layers.

The first light-emitting region 110 may further include a second conductivity type semiconductor layer 119 disposed over the first active layer 118. The second conductivity type semiconductor layer 119 may include a phosphide or nitride semiconductor such as (Al, Ga, In)P or (Al, Ga, In)N. The second conductivity type semiconductor layer 119 may be doped with a conductivity type opposite to that of the first conductivity type semiconductor layer 111. For example, the second conductivity type semiconductor layer 119 may be doped as a p-type by including an impurity such as Mg.

The first light-emitting region 110 may have a light-emitting surface formed on a side of the first conductivity type semiconductor layer 111 or the second conductivity type semiconductor layer 119. For example, first light generated in the first active layer 118 may be emitted to the outside through the first conductivity type semiconductor layer 111, or may be emitted to the outside through the second conductivity type semiconductor layer 119. A uneven structure may be formed on one surface of the first conductivity type semiconductor layer 111 or one surface of the second conductivity type semiconductor layer 119 so as to increase light extraction efficiency.

The first light-emitting region 110 may include three active layers 112, 115, and 118 between the first conductivity type semiconductor layer 111 and the second conductivity type semiconductor layer 119, among the three active layers 112, 115, and 118, two of which are disposed in a lower portion are the first and second non-emitting active layers 112 and 115, and a remaining one disposed in an upper portion is the first active layer 118, which may emit first light when power is applied to the first light-emitting region 110.

Meanwhile, the first and second non light-emitting active layers 112 and 115 and the first active layer 118 may include a same group V material. Alternatively, the first and second non light-emitting active layers 112 and 115 may include a same group III material. In this case, contents of group V material or group III material in each of the active layers 112, 115, and 118 may be different from one another.

FIG. 1 exemplarily illustrates that the first light-emitting region 110 includes two non light-emitting active layers 112 and 115, but it is obvious that an example in which the first light-emitting region 110 includes three or more of the non light-emitting active layers 112 and 115 is also possible.

Next, the second light-emitting region 120 may include a first conductivity type semiconductor layer 121 disposed on one surface of the substrate 101, a first non light-emitting active layer 122 disposed over the first conductivity type semiconductor layer 121, and a second active layer 125 disposed over the first non light-emitting active layer 122.

The first non light-emitting active layer 122 may be an active layer that does not emit light when power is applied to the second light-emitting region 120, and the second active layer 125 may be an active layer that emits second light when power is applied to the second light-emitting region 120.

The first conductivity type semiconductor layer 121 may be configured to be identical or similar to the first conductivity type semiconductor layer 111 of the first light-emitting region 110. A buffer layer may be further disposed between the first conductivity type semiconductor layer 121 of the second light-emitting region 120 and the substrate 101.

The first non light-emitting active layer 122 may be configured to be identical or similar to the first non light-emitting active layer 112 of the first light-emitting region 110.

The second light-emitting region 120 may further include a pre-strain layer disposed between the first non light-emitting active layer 122 and the first conductivity type semiconductor layer 121. The pre-strain layer may be configured to be identical or similar to the pre-strain layer of the first light-emitting region 110.

The second active layer 125 is an active layer disposed on the first non light-emitting semiconductor layer 122, may include a phosphide or nitride semiconductor such as (Al, Ga, In)P or (Al, Ga, In)N, and may be grown on the first non light-emitting semiconductor layer 122 using a technique such as MOCVD, MBE, HVPE, or the like.

In addition, the second active layer 125 may include a quantum well structure (QW) including at least two barrier layers and at least one well layer, and moreover, may include a multi quantum well structure (MQW) including a plurality of barrier layers and a plurality of well layers. A wavelength of light emitted from the second active layer 125 may be adjusted by controlling a composition ratio of materials forming the well layer. In this case, the well layers may include a same element in common, for example, In.

The second active layer 125 may be configured to be identical to or similar to the second non light-emitting active layer 115 of the first light-emitting region 110, except that it emits light when power is applied to the second light-emitting region 120.

A number of pairs of the barrier layers and the well layers of the first non light-emitting active layer 122 may be different from that of pairs of the second active layer 125. An indium content of the first non light-emitting active layer 122 may be different from that of the second active layer 125.

The second light-emitting region 120 may further include a first connection region 124 disposed between the first non light-emitting active layer 122 and the second active layer 125. The first connection region 124 may be configured to be identical to or similar to the first connection region 114 of the first light-emitting region 110.

The first connection region 124 may be a conductive semiconductor layer doped with first and second conductive dopants. A doping concentration of the first connection region 124 may be higher than those of the first non light-emitting active layer 122 and the second active layer 125.

A lower portion of the first connection region 124 may be a layer doped with a first conductive dopant, and an upper portion of the first connection region 124 may be a layer doped with a second conductive dopant. Conversely, the lower portion of the first connection region 124 may be a layer doped with a second conductive dopant, and the upper portion of the first connection region 124 may be a layer doped with a first conductive dopant.

The first light-emitting region 120 may further include a second connection region 127 disposed over the second active layer 125. The second connection region 127 may be configured to be identical to or similar to the second connection region 117 of the first light-emitting region 110.

The second connection region 127 may be a conductive semiconductor layer doped with first and second conductive dopants. A doping concentration of the second connection region 127 may be higher than that of the second active layer 125.

A lower portion of the second connection region 127 may be a layer doped with a first conductive dopant, and an upper portion of the second connection region 127 may be a layer doped with a second conductive dopant. Conversely, the lower portion of the second connection region 127 may be a layer doped with a second conductive dopant, and the upper portion of the second connection region 127 may be a layer doped with a first conductive dopant.

In addition, the second light-emitting region 120 may further include a first carrier barrier layer 123 disposed between the first non light-emitting active layer 122 and the second active layer 125 and a second carrier barrier layer 126 disposed over the second active layer 125.

The first carrier barrier layer 123 may be disposed between the first non light-emitting active layer 122 and the first connection region 124. The first carrier barrier layer 123 may be configured to be identical or similar to the first carrier barrier layer 113 of the first light-emitting region 110.

The first carrier barrier layer 123 is a layer for controlling and blocking a movement of carriers distributed within the first non light-emitting active layer 122 and the second active layer 125, and various configurations are possible. The first non light-emitting active layer 122 and the second active layer 125 may be isolated by the first carrier barrier layer 123.

The first carrier barrier layer 123 may have a band gap energy greater than those of the barrier layers of the first non-emitting active layer 122 and the second active layer 125. A thickness of the first carrier barrier layer 123 may be within the range of 5 nm to 500 nm.

The first carrier barrier layer 123 may be a layer including InₓAl_{y}Ga_{(1-x-y)}N (0≤x≤1, 0≤y≤1). In addition, the first carrier barrier layer 123 may be doped at a concentration lower than that of the first conductivity type semiconductor layer 121 or may not be doped.

The second carrier barrier layer 126 may be disposed over the second active layer 125. In addition, the second carrier barrier layer 126 may be disposed between the second active layer 125 and the second connection region 127. The second carrier barrier layer 126 may be configured to be identical to or similar to the first carrier barrier layer 116 of the first light-emitting region 110.

The second carrier barrier layer 126 may have a band gap energy greater than those of the barrier layers of the first non light-emitting active layer 122 and the second active layer 125. A thickness of the second carrier barrier layer 126 may be within the range of 5 nm to 500 nm.

The second carrier barrier layer 126 may be a layer including InₓAl_{y}Ga_{(1-x-y)}N (0≤x≤1, 0≤y≤1). In addition, the second carrier barrier layer 126 may be doped at a concentration lower than that of the first conductivity type semiconductor layer 121 or may not be doped.

The thickness or band gap energy of the second carrier barrier layer 126 may be same as or different from the thickness or band gap energy of the first carrier barrier layer 123.

The second light-emitting region 120 may have a light-exiting surface formed on a side of the first conductivity type semiconductor layer 121 or the second connection region 127 through which light is emitted. For example, second light generated in the second active layer 125 may be emitted to the outside through the first conductivity type semiconductor layer 121, or may be emitted to the outside through the second connection region 127.

The first light-emitting region 120 may include two active layers 122 and 125 between the first conductivity type semiconductor layer 121 and the second connection region 127, among the three active layers 122 and 125, one disposed in a lower portion is the first non light-emitting active layer 122, and the other disposed in an upper portion is the second active layer 125, which may emit light when power is applied to the second light-emitting region 120.

FIG. 1 exemplarily illustrates that the second light-emitting region 120 includes one non light-emitting active layer 122, but it is obvious that an example in which the second light-emitting region 120 includes two or more non light-emitting active layers 122 is also possible.

Next, the third light-emitting region 130 may include a first conductivity type semiconductor layer 131 disposed on one surface of the substrate 101, and a third active layer 132 disposed over the first conductivity type semiconductor layer 131.

The third active layer 132 may be an active layer that emits light when power is applied to the third light-emitting region 130. The third light-emitting region 130 may not include a non light-emitting active layer.

The first conductivity type semiconductor layer 131 may be configured to be identical to or similar to the first conductivity type semiconductor layers 111 and 121 of the first light-emitting region 110 and the second light-emitting region 120. A buffer layer may be further disposed between the first conductivity type semiconductor layer 131 of the third light-emitting region 130 and the substrate 101.

The third active layer 132 may be configured to be identical or similar to the first non light-emitting active layer 112 of the first light-emitting region 110 or the first non light-emitting active layer 122 of the second light-emitting region 120.

The third light-emitting region 130 may further include a pre-strain layer disposed between the third active layer 132 and the first conductivity type semiconductor layer 121. The pre-strain layer may be configured to be identical to or similar to the pre-strain layer of the first light-emitting region 110 or the second light-emitting region 120.

The third active layer 132 is an active layer disposed on the first conductivity type semiconductor layer 131, may include a phosphide or nitride semiconductor such as (Al, Ga, In)P or (Al, Ga, In)N, and may be grown on the first conductivity type semiconductor layer 131 using a technique such as MOCVD, MBE, HVPE, or the like.

In addition, the third active layer 132 may include a quantum well structure (QW) including at least two barrier layers and at least one well layer, and moreover, may include a multi quantum well structure (MQW) including a plurality of barrier layers and a plurality of well layers. A wavelength of light emitted from the third active layer 132 may be adjusted by controlling a composition ratio of materials forming the well layer. In this case, the well layers may include a same element in common, for example, In.

The third active layer 132 may be configured to be identical to or similar to the first non light-emitting active layer 112 of the first light-emitting region 110 or the first non light-emitting active layer 122 of the second light-emitting region 120, except that it emits light when power is applied to the third light-emitting region 130.

The third light-emitting region 120 may further include a first connection region 134 disposed over the third light-emitting layer 132. The first connection region 134 may be configured to be identical to or similar to the first connection region 113 of the first light-emitting region 110 or the first connection region 123 of the second light-emitting region 120.

The first connection region 134 may be a conductive semiconductor layer doped with first and second conductive dopants. A doping concentration of the first connection region 134 may be higher than that of the third active layer 132.

A lower portion of the first connection region 134 may be a layer doped with a first conductive dopant, and an upper portion of the first connection region 124 may be a layer doped with a second conductive dopant. Conversely, the lower portion of the first connection region 134 may be a layer doped with a second conductive dopant, and the upper portion of the first connection region 134 may be a layer doped with a first conductive dopant.

In addition, the third light-emitting region 130 may further include a first carrier barrier layer 133 disposed over the third active layer 132.

The first carrier barrier layer 133 may be disposed between the third active layer 132 and the first connection region 134. The first carrier barrier layer 133 may be configured to be identical to or similar to the first carrier barrier layer 113 of the first light-emitting region 110 or the first carrier barrier layer 123 of the second light-emitting region 120.

The first carrier barrier layer 133 may have a band gap energy greater than that of the barrier layer of the third active layer 132. A thickness of the first carrier barrier layer 133 may be within the range of 5 nm to 500 nm.

The first carrier barrier layer 133 may be a layer including InₓAl_{y}Ga_{(1-x-y)}N (0≤x≤1, 0≤y≤1). In addition, the first carrier barrier layer 133 may be doped at a concentration lower than that of the first conductivity type semiconductor layer 131 or may not be doped.

The third light-emitting region 130 may have a light-emitting surface formed on a side of the first conductivity type semiconductor layer 131 or the first connection region 134 through. For example, light generated in the third active layer 132 may be emitted to the outside through the first conductivity type semiconductor layer 131, or may be emitted to the outside through the first connection region 134.

The third light-emitting region 130 may include one active layer 132 between the first conductivity type semiconductor layer 131 and the first connection region 124, and the active layer 132 may emit light when power is applied to the third light-emitting region 130.

FIG. 1 exemplarily illustrates that the third light-emitting region 130 includes only the third active layer 132, but it is obvious that an example in which the third light-emitting region 130 includes one or more non light-emitting active layers is also possible.

Meanwhile, the first through third light-emitting regions 110, 120, and 130 may include a second electrode 150 disposed over the first through third active layers 118, 125, and 132, respectively.

In addition, the light emitting module 100 may further include an insulating layer 160 covering the first through third light-emitting regions 110, 120, and 130.

In this case, in the first light-emitting region 110, a contact surface connected to a first electrode 140 may be formed in the second connection region 117 exposed through an opening of the insulation layer 160. A connection electrode portion 170 for electrical connection may be disposed between the contact surface of the second connection region 117 and the first electrode 140. The connection electrode portion 170 may extend along a space between the first light-emitting region 110 and the second and third light-emitting regions 120 and 130. A width of the space may vary depending on a distance from the substrate 101. For example, the width of the space may increase as it is farther from the substrate 101.

In the second light-emitting region 120, a contact surface connected to the first electrode 140 may be formed in the first connection region 124 exposed through an opening of the insulation layer 160. A connection electrode portion 170 for electrical connection may be disposed between the contact surface of the first connection region 124 and the first electrode 140. The connection electrode portion 170 may extend along a space between the second light-emitting region 120 and the first and third light-emitting regions 110 and 130.

In the third light-emitting region 130, a contact surface connected to the first electrode 140 may be formed in the first conductivity type semiconductor layer 131 disposed between the substrate 101 and the third active layer 132 and exposed through an opening of the insulation layer 160. A connection electrode portion 170 for electrical connection may be disposed between the contact surface of the first conductivity type semiconductor layer 131 and the first electrode 140. The connection electrode portion 170 may extend along a space between the third light-emitting region 130 and the first and second light-emitting regions 110 and 120.

Accordingly, in a case of the first light-emitting region 110, a current path may be formed between the second connection region 117 and the second electrode 150 when power is applied. Therefore, first light may be generated and emitted through the first active layer 118 disposed between the second connection region 117 and the second electrode 150, and the first active layer 118 may function as an active layer contributing to a light emission of the first light-emitting region 110. In the first light-emitting region 110, the first and second non light-emitting active layers 112 and 115 cannot contribute to light emission because they deviate from the path of current applied to the first light-emitting region 110.

Similarly, in a case of the second light-emitting region 120, a current path may be formed between the first connection region 124 and the second electrode 150 when power is applied. Therefore, second light may be generated and emitted through the second active layer 125 disposed between the first connection region 124 and the second electrode 150, and the second active layer 125 may function as an active layer contributing to a light emission of the second light-emitting region 120. In the second light-emitting region 120, the first non light-emitting active layer 122 cannot contribute to light emission because it deviates from the path of current applied to the second light-emitting region 120.

In a case of the third light-emitting region 130, a current path may be formed between the first conductivity type semiconductor layer 131 and the second electrode 150 when power is applied. Therefore, third light may be generated and emitted through the third active layer 132 disposed between the first conductivity type semiconductor layer 131 and the second electrode 150, and the third active layer 132 may function as an active layer contributing to light emission of the third light-emitting region 130.

A thickness of the first connection region 114 in the first light-emitting region 110 may be smaller than those of the first connection regions 124 and 134 of the second and third light-emitting regions 120 and 130. The thickness of the first connection region 124 in the second light-emitting region 120 may be smaller than that of the first connection region 134 in the third light-emitting region 130.

The first through third light-emitting regions 110, 120, and 130 may be spaced apart from one another on one surface of the substrate 101 at an interval. The first through third light-emitting regions 110, 120, and 130 may be defined as individual light-emitting regions by etching and laterally isolating portions of layers sequentially stacked on the substrate 101.

In addition, the second light-emitting region 120 may be identical in shape to the first light-emitting region 110 after the second conductivity type semiconductor layer 119 and the first active layer 118 have been etched. The third light-emitting region 130 may have a same shape as a shape after the second conductivity type semiconductor layer 119, the first active layer 118, the second connection region 117, the second carrier barrier layer 116, and the second non light-emitting active layer 115 of the first light-emitting region 110 are etched.

Meanwhile, the first through third light-emitting regions 110, 120, and 130 may be laterally spaced apart from one another on the substrate 101.

For example, the connection electrode portion 170 for electrical connection with the first electrode 140 may be disposed in a space between the first through third light-emitting regions 110, 120, and 130, and the connection electrode portion 170 may be spaced apart from adjacent light-emitting regions 110, 120, and 130. Alternatively, a reflection layer or an insulation layer may be disposed in the space between the first through third light-emitting regions 110, 120, and 130. In a case that the space between the first through third light-emitting regions 110, 120, and 130 is filled with the reflection layer or the insulation layer, each of the light-emitting regions 110, 120, and 130 may be securely supported, and electrical insulation between each of the light-emitting regions 110, 120, and 130 may be improved.

Areas of regions from which light is emitted in the first light-emitting region 110 through the third light-emitting region 130 may be same or different from one another. Light-emitting areas in the first light-emitting region 110 through the third light-emitting region 130 may be different depending on a wavelength of light emitted from each of the light-emitting regions 110, 120, and 130. For example, a light-emitting area of light-emitting region 110, 120, or 130 that emits light of a wavelength requiring a large amount of light may be made larger than that of another light-emitting region 110, 120, or 130.

In addition, in a case of FIG. 1, the light emitting module 100 is exemplarily illustrated as including three light-emitting regions 110, 120, and 130 by including each one of the first through third light-emitting regions 110, 120, and 130, but each of the light-emitting regions 110, 120, and 130 may be provided in a plurality. For example, the light-emitting region 110, 120, or 130 that emits light of a wavelength requiring a large amount of light may include a number thereof greater than that of another light-emitting region 110, 120, or 130.

Meanwhile, first through third light emitted from the first through third light-emitting regions 110, 120, and 130 may have peak wavelengths different from one another. That is, first through third light emitted from the first through third active layers 118, 125, and 132 may have peak wavelengths different from one another. In addition, In contents in the well layers of the first through third active layers 118, 125, and 132 may be different from one another.

For example, the first active layer 118 may be an active layer that emits light having a peak wavelength within a red wavelength range. A number of pairs of the well layer-barrier layer of the first active layer 118 may be 1 to 4. A well layer thickness of the third active layer 118 may be 2 nm to 4 nm. A barrier layer thickness of the first active layer 118 may be larger than those of the second and third active layers 125 and 132. The red light may have a difference between a peak wavelength and a dominant wavelength of 5 to 30 nm. In detail, the first active layer 118 may emit light having the peak wavelength between 620 nm and 640 nm, and may have the dominant wavelength between 600 nm and 630 nm. By keeping the difference between the peak wavelength, a color deviation may be reduced, thereby resulting in more vivid color expression. The peak wavelength of red light may be longer than that of the dominant wavelength. Through this, it is possible to correct for eye sensitivity while increasing light energy, thereby reducing a design difficulty.

For example, the second active layer 125 may be an active layer that emits light having a peak wavelength within a green wavelength range. A number of pairs of the well layer-barrier layer of the first active layer 125 may be 1 to 4. A well layer thickness of the second active layer 125 may be 2 nm to 4 nm. A barrier layer thickness of the second active layer 125 may be 8 nm to 12 nm. Green light may have a difference between a peak wavelength and a dominant wavelength of 5 nm to 20 nm. In detail, green light may have the peak wavelength between 510 nm and 540 nm, and may have the dominant wavelength between 525 nm and 542 nm. By keeping the difference between the peak wavelength and the dominant wavelength small, a color deviation may be reduced, thereby resulting in more vivid color expression. The peak wavelength of green light may be shorter than that of the dominant wavelength. Through this, it is possible to correct for eye sensitivity while increasing the light energy, thereby reducing the design difficulty.

For example, the third active layer 132 may be an active layer that emits light having a peak wavelength within a blue wavelength range. A number of pairs of the well layer-barrier layer of the third active layer 132 may be 3 to 8. The number of pairs of the third active layer 132 may be greater than those of pairs of the first and second active layers 118 and 125. A well layer thickness of the third active layer 132 may be 2 nm to 4 nm. A thickness of the barrier layer of the third active layer 132 may be 8 nm to 12 nm. Blue light may have a difference between a peak wavelength and a dominant wavelength of 2 nm to 15 nm. In detail, blue light may have the peak wavelength between 430 nm and 475 nm, and may have the dominant wavelength between 460 nm and 480 nm. By keeping the difference between the peak wavelength and the dominant wavelength small, the color deviation may be reduced, thereby resulting in more vivid color expression. The peak wavelength of blue light may be shorter than that of the dominant wavelength. Through this, it is possible to correct the luminous efficacy while increasing the light energy, thereby reducing the design difficulty.

The first through third light-emitting regions 11, 120, and 130 may be configured to emit orange light, yellow light, purple light, or ultraviolet light in addition to blue light, green light, and red light.

The first through third light-emitting regions 110, 120, and 130 may implement light-emitting regions of various colors including three primary colors by a simple method of vertically and continuously stacking and etching the first conductivity type semiconductor layer, the plurality of active layers emitting light of different peak wavelengths, and the second conductivity type semiconductor layer on the substrate 101. Accordingly, there is no need to transfer individually grown light emitting portions onto the substrate, thereby simplifying a process. In addition, the process is simplified because there is no need for an adhesive layer between vertically stacked active layers, and failure or damage caused by deformation or peeling of the adhesive layer due to heat may be prevented.

In addition, it is possible to increase an amount of light by securing large light-emitting areas through which light is emitted from the first through third light-emitting regions 110, 120, and 130. In detail, even when one light-emitting region 110, 120, or 130 includes a plurality of stacked active layers, since they are non-emission active layers except for one of the plurality of active layers, an area of a semiconductor layer that needs to be removed so as to apply power to the light-emitting regions 110, 120, and 130 may be minimized. As a result, the light-emitting areas of the light-emitting regions 11, 120, and 130 may be maximized.

In addition, the numbers of active layers (including non light-emitting active layers) included in the first through third light-emitting regions 110, 120, and 130 are different from one another, and thus, the luminous intensity of light emitted from each of the light-emitting regions 110, 120, and 130 may be adjusted and the wavelength thereof may be finely adjusted, thereby increasing color accuracy and clarity, improving efficiency, extending lifespan, and optimizing visibility.

Active layers positioned at a same height in the first through third light-emitting regions 110, 120, and 130 may have a deviation in In contents in the well layers of less than 10%. For example, the first non light-emitting active layer 112 of the first light-emitting region 110, the first non light-emitting active layer 122 of the second light-emitting region 120, and the third active layer 132 of the third light-emitting region 130 are active layers positioned at a same height, and may have a deviation in In contents in the well layers of less than 10%. The second non light-emitting active layer 115 of the first light-emitting region 110 and the second active layer 125 of the second light-emitting region 120 are active layers positioned at a same height, and may have a deviation in In contents in the well layers of less than 10%.

Meanwhile, the first through third light-emitting regions 110, 120, and 130 may have different heights from an upper surface of the substrate 101 to the first through third active layers 118, 125, and 132. Therefore, a stress in a lower portion may be sufficiently relieved, so that internal defects may be eliminated by having a light-emitting region with a high height, thereby increasing luminous efficiency.

The first active layer 118 may be disposed at a farthest position from the upper surface of the substrate 101, and the third active layer 132 may be disposed at a closest position to the upper surface of the substrate 101. The second active layer 125 may be positioned between the first active layer 118 and the third active layer 132.

Accordingly, first light emitted from the first active layer 118 does not affect a light emission of the second active layer 125 or the third active layer 132, second light emitted from the second active layer 125 does not affect a light emission of the first active layer 118 or the third active layer 132, and third light emitted from the third active layer 132 may not affect a light emission of the first or second active layer 118 or 125, either. That is, a PL (Photoluminescence) phenomenon may be prevented between adjacent light-emitting regions 110, 120, and 130.

In addition, heights from the upper surface of the substrate 101 to a contact surface with the second electrode 150 for each of the first through third light-emitting regions 110, 120, and 130 may be different from one another. In addition, heights from the upper surface of the substrate 101 to the second electrode 150 for each of the first through third light-emitting regions 110, 120, and 130 may be different from one another. The second electrode 150 of the first light-emitting region 110 may be disposed at a farthest position from the upper surface of the substrate 101, and the second electrode 150 of the third light-emitting region 130 may be disposed at a closest position to the upper surface of the substrate 101. The second electrode 150 of the second light-emitting region 120 may be positioned therebetween.

In addition, from the upper surface of the substrate 101 to a contact surface of the connection electrode portion 170 for each of the first through third light-emitting regions 110, 120, and 130 may be different from one another. In addition, vertical lengths of the connection electrode portion 170 connected to the contact surface from the upper surface of the substrate 101 for each of the first through third light-emitting regions 110, 120, and 130 may be different from one another.

Meanwhile, the contact surface that contacts the connection electrode portion 170 among the first light-emitting region 110 may be positioned in the second connection region 117, the contact surface that contacts the connection electrode portion 170 among the second light-emitting region 120 may be positioned in the first connection region 124, and the contact surface that contacts the connection electrode portion 170 among the third light-emitting region 130 may be positioned in the first conductivity type semiconductor layer 131. In this case, concentrations of a first or second conductive dopant in regions where each of the contact surfaces are formed may be different from one another. Similarly, the contact surface that contacts the second electrode 150 among the first light-emitting region 110 may be positioned in the second conductivity type semiconductor layer 119, the contact surface that contacts the second electrode 150 among the second light-emitting region 120 may be positioned in the second connection region 127, and the contact surface that contacts the second electrode 150 among the third light-emitting region 130 may be positioned in the first connection region 134. In this case, concentrations of a first or second conductive dopant in regions where each of the contact surfaces are formed may be different from one another. Through this, doping concentrations appropriate for the wavelength of light emitted from each of the light-emitting regions 110, 120, and 130 may be appropriately set, thereby optimizing conditions such as resistance, heat generation, and light-emitting temperature.

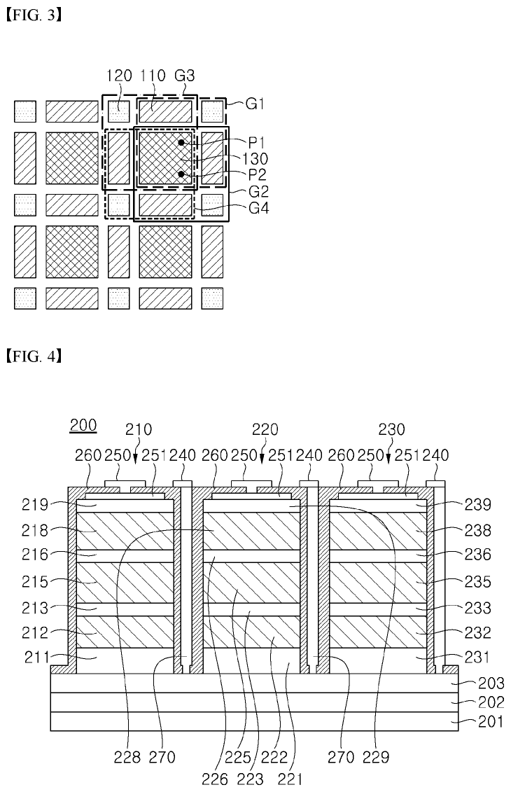

FIG. 2 is a plan view showing a light-emitting surface of the light emitting module 100, and shows a shape in which the first through third light-emitting regions 110, 120, and 130 are arranged on the light-emitting surface. In the light emitting module 100, respective light emitting areas of the first through third light-emitting regions 110, 120, and 130 may be different. Considering a visual sensitivity ratio of the human eye (RGB 3:6:1), respective light-emitting areas, numbers, and patterns may be determined. FIG. 3 illustrates a modified example of FIG. 2, and it is obvious that respective light-emitting regions or arrangement patterns of first through third light-emitting regions 110, 120, and 130 are not limited to a specific form. In a case that a light emitting module 100 forms a region including the first and second light-emitting regions 110 and 120 in a first direction and the second and third light-emitting regions 120 and 130 in a second direction into groups G1, G2, G3, and G4, one group G1, G2, G3, or G4 may further include an additional light-emitting region 110, 120, or 130 that emits a same color as that of at least one of the first, second, or third light-emitting region 110, 120, or 130. The region forming the groups G1, G2, G3, and G4 may have a rectangular shape having the first direction and the second direction perpendicular thereto.

Alternatively, the first group G1 and the second group G2 may include three light-emitting regions 110, 120, and 130 that emit light of peak wavelengths different from one another. The third group G3 and the fourth group G4 may also include three light-emitting regions 110, 120, and 130 that emit light of peak wavelengths different from one another.

In addition, in a case that the groups G1, G2, G3, and G4 are formed so that at least one of the light-emitting regions 110, 120, and 130 is overlapped therein, a PPI of the light emitting module 100 may be increased due to light-emitting regions 110, 120, and 130 overlapped in adjacent groups G1, G2, G3, and G4. For example, in FIGS. 2 and 3, the first group G1 and the second group G2 may be formed so that the first light-emitting region 110 and the second light-emitting region 120 are overlapped therein, thereby increasing the PPI of the light emitting module 100. In this case, a pitch which is a distance between a center P1 of the first group G1 and a center P2 of the second group G2 may be formed much smaller, thereby increasing a resolution.

In addition, in the case that the groups G1, G2, G3, and G4 are formed so that at least one of the light-emitting regions 110, 120, and 130 is overlapped therein, a light-emitting region 110, 120, 130 or 140 is overlapped in all of first through fourth groups G1, G2, G3, and G4 may be disposed at a center to form a central light-emitting region. For example, as in FIG. 2, the second light-emitting region 120 may be overlapped in all of the first through fourth groups G1, G2, G3, and G4 to form the central light-emitting region, or as in FIG. 3, the third light-emitting region 130 may be overlapped in all of the first through fourth groups G1, G2, G3, and G4 to form the central light-emitting region. In addition, three light-emitting regions 110, 120, and 130 are disposed in the first or second direction for one group G1, G2, G3, or G4, but four groups G1, G2, G3, and G3 overlapped with one another with respect to the central light-emitting region may be formed. That is, the PPI of the light emitting module 100 may be increased by forming a greater number of groups G1, G2, G3, and G4 than a number of the light-emitting regions 110, 120, and 130 disposed in the first direction or the second direction.

Back in FIG. 2, the first group G1 may include four light-emitting regions 110, 120, and 130 having a 2×2 grid pattern within a square region in the first direction and the second direction. When the first direction is referred to as a row direction and the second direction is referred to as a column direction, the second group G2 may include four light-emitting regions 110, 120, and 130 having a 2×2 grid pattern within a square region shifted by one row or column from the first group G1. In this case, the first group G1 and the second group G2 may include at least one light-emitting region in common.

Meanwhile, in the case of FIG. 1, it is exemplarily described that the first active layer 118 of the first light-emitting region 110 emits light in a red wavelength band, the second active layer 125 of the second light-emitting region 120 emits light in a green wavelength band, and the third active layer 132 of the third light-emitting region 130 emits light in a blue wavelength band, but this is only an example, and the present invention is not limited thereto. It is obvious that other modifications, such as the first active layer 118 of the first light-emitting region 110 emitting light in the blue wavelength band, the second active layer 125 of the second light-emitting region 120 emitting light in the green wavelength band, and the third active layer 132 of the third light-emitting region 130 emitting light in the red wavelength band, are also possible. Each of the light-emitting regions 110, 120, and 130 of the light emitting module 100 may be individually controlled for operation.

FIG. 4 illustrates a light emitting module 200 according to a second embodiment of the present invention, in which the light emitting module 200 may include a substrate 201 and a plurality of light-emitting regions 210, 220, and 230 disposed on one surface of the substrate 201. Hereinafter, the light emitting module 200 according to the second embodiment will be described in detail focusing on differences from the light emitting module 100 according to the first embodiment.

The substrate 201 may be configured to be identical or similar to the substrate 101 of the light emitting module 100 according to the first embodiment.

The light emitting module 200 may include a first conductivity type semiconductor layer 203 disposed on an upper surface of the substrate 201. The first conductivity type semiconductor layer 203 may be a semiconductor layer grown on one surface of the substrate 201, and may include a phosphide or nitride semiconductor such as (Al, Ga, In)P or (Al, Ga, In)N. In addition, the first conductivity type semiconductor layer 203 may be doped as an n-type by including one or more impurities such as Si, C, Ge, Sn, Te, Pb, or others. The present invention is not limited thereto, and as another example, the first conductivity type semiconductor layer 203 may be doped with an opposite conductivity type, including a p-type dopant. In addition, the first conductivity type semiconductor layer 203 may be formed as a single layer or multiple layers.

The light emitting module 200 may further include a buffer layer 202 disposed between the substrate 201 and the first conductivity type semiconductor layer 203.

The plurality of light-emitting regions 210, 220, and 230 may be spaced apart from one another on one surface of the substrate 201. In addition, the plurality of light-emitting regions 210, 220, and 230 may be independently controlled.

Power applied to the plurality of light-emitting regions 210, 220, and 230 may be independently controlled. Referring to FIG. 4, for example, the light emitting module 200 may include a first light-emitting region 210, a second light-emitting region 220, and a third light-emitting region 230 that are spaced apart from one other.

At least one of the first through third light-emitting regions 210, 220, and 230 may include a plurality of vertically stacked active layers. The light-emitting regions 210, 220, and 230 including the plurality of active layers may have dominant wavelengths of light emitted from the light-emitting regions 110, 120, and 130 varied depending on a current applied thereto.

For example, the first through third light-emitting regions 210, 220, and 230 may all include the plurality of vertically stacked active layers. In this case, numbers of active layers included in each of the first through third light-emitting regions 210, 120, and 130 may be same.

For example, the first light-emitting region 210 is a light-emitting region including the plurality of active layers, and the first light-emitting region 210 may include a first active layer 212 disposed on the first conductivity type semiconductor layer 203, a first carrier barrier layer 213 disposed on the first active layer 212, a second active layer 215 disposed on the first carrier barrier layer 213, a second carrier barrier layer 216 disposed on the second active layer 215, a third active layer 218 disposed on the second carrier barrier layer 216, and a second conductivity type semiconductor layer 219 disposed on the third active layer 218.

The first light-emitting region 210 may further include a pre-strain layer 211 disposed between the first conductivity type semiconductor layer 203 and the first active layer 212. The pre-deformation layer 211 may include a single layer or a plurality of sub-layers. At least one of the plurality of sub-layers may be a Si doped layer. In addition, one of the plurality of sub-layers may be a superlattice layer periodically stacked with layers of different compositions. The superlattice layer may include InGaN/GaN. In addition, the pre-strain layer 211 may include a layer including In. In addition, the pre-strain layer 211 may include a region where an In composition decreases in concentration as it is farther from the substrate 201.

The first active layer 212 is a light-emitting layer disposed on the first conductivity type semiconductor layer 203, may include a phosphide or nitride semiconductor such as (Al, Ga, In)P or (Al, Ga, In)N, and may be grown on the first conductivity type semiconductor layer 203 using a technique such as MOCVD, MBE, HVPE, or the like.

In addition, the first active layer 212 may include a quantum well structure (QW) including at least two barrier layers and at least one well layer, and moreover, may include a multi quantum well structure (MQW) including a plurality of barrier layers and a plurality of well layers. A wavelength of light emitted from the first active layer 212 may be adjusted by controlling a composition ratio of materials forming the well layer. In this case, the well layers may include a same element in common, for example, In.

For example, the first active layer 212 may be an active layer that emits light having a peak wavelength within a blue wavelength range. A number of pairs of the barrier layers and the well layers in the first active layer 212 may be 8 or less. Alternatively, the number of pairs of the barrier layers and the well layers in the first active layer 212 may be 3 or more and 8 or less. Alternatively, the number of pairs of the barrier layers and the well layers in the first active layer 212 may be 6 or less. The number of pairs of the first active layer 212 may be greater than those of pairs of the second and third active layers 215 and 218. That is, the number of pairs of the first active layer 212 may be a greatest. A well layer thickness of the third active layer 212 may be 2 nm to 4 nm. A barrier layer thickness of the first active layer 212 may be 8 nm to 12 nm. Blue light may have a difference between a peak wavelength and a dominant wavelength of 2 nm to 15 nm. In detail, blue light may have the peak wavelength between 430 nm and 475 nm, and may have the dominant wavelength between 460 nm and 480 nm. By keeping the difference between the peak wavelength and the dominant wavelength small, a color deviation may be reduced, thereby resulting in more vivid color expression. The peak wavelength of blue light may be shorter than that of the dominant wavelength. Through this, it is possible to correct for eye sensitivity' while increasing light energy, thereby reducing a design difficulty.

The carrier barrier layer 213 may be disposed between the first active layer 212 and the second active layer 215. The first carrier barrier layer 213 is a layer for controlling and blocking a movement of carriers distributed within the first active layer 212 and the second active layer 215, and various configurations are possible. The first active layer 212 and the second active layer 215 may be isolated by the first carrier barrier layer 213.

The first carrier barrier layer 213 may have a band gap energy greater than those of barrier layers of adjacent first active layer 212 and second active layer 215. A thickness of the first carrier barrier layer 213 may be within a range of 5 nm to 500 nm.

The first carrier barrier layer 213 may be a layer including InₓAl_{y}Ga_{(1-x-y)}N (0≤x≤1, 0≤y≤1).

In addition, the first carrier barrier layer 213 may be doped at a concentration lower than that of the first conductivity type semiconductor layer 203 or may not be doped.

The second active layer 215 is a light-emitting layer disposed on the first active layer 212, may include a phosphide or nitride semiconductor such as (Al, Ga, In)P or (Al, Ga, In)N, and may be grown on the first carrier barrier layer 213 using a technique such as MOCVD, MBE, HVPE, or the like.

In addition, the second active layer 215 may include a quantum well structure (QW) including at least two barrier layers and at least one well layer, and moreover, may include a multi quantum well structure (MQW) including a plurality of barrier layers and a plurality of well layers. A wavelength of light emitted from the second active layer 215 may be adjusted by controlling a composition ratio of materials forming the well layer. In this case, the well layers may include a same element in common, for example, In.

An indium composition of the second active layer 215 may be different from that of the first active layer 212. A peak wavelength of light emitted from the second active layer 215 may be different from that of light emitted from the first active layer 212.

For example, the second active layer 215 may be an active layer that emits light having the peak wavelength within a green wavelength range. A number of pairs of the barrier layers and the well layers in the second active layer 215 may be 6 or less. Alternatively, the number of pairs of the barrier layers and the well layers in the second active layer 215 may be 4 or less. Alternatively, the number of pairs of the barrier layers and the well layers in the second active layer 215 may be 3 or less. A well layer thickness of the second active layer 215 may be 2 nm to 4 nm. A barrier layer thickness of the second active layer 215 may be 8 nm to 12 nm. Green light may have a difference between a peak wavelength and a dominant wavelength of 5 nm to 20 nm. In detail, green light may have the peak wavelength between 510 nm and 540 nm, and may have the dominant wavelength between 525 nm and 542 nm. By keeping the difference between the peak wavelength and the dominant wavelength small, the color deviation may be reduced, thereby resulting in more vivid color expression. The peak wavelength of green light may be shorter than that of the dominant wavelength. Through this, it is possible to correct for eye sensitivity while increasing the light energy, thereby reducing the design difficulty.

The second carrier barrier layer 216 may be disposed between the second active layer 215 and the third active layer 218.

The second carrier barrier layer 216 is a layer for controlling and blocking a movement of carriers distributed within the second active layer 215 and the third active layer 218, and various configurations are possible. The second active layer 215 and the third active layer 218 may be isolated by the second carrier barrier layer 216.

The second carrier barrier layer 216 may have a band gap energy greater than those of barrier layers of adjacent second active layer 215 and third active layer 218. A thickness of the second carrier barrier layer 216 may be within the range of 5 nm to 500 nm.

The second carrier barrier layer 216 may be a layer including InₓAl_{y}Ga_{(1-x-y)}N (0≤x≤1, 0≤y≤1).

In addition, the second carrier barrier layer 216 may be doped at a concentration lower than that of the first conductivity type semiconductor layer 203 or may not be doped.

The thickness or band gap energy of the second carrier barrier layer 216 may be same as or different from the thickness or band gap energy of the first carrier barrier layer 216.

The third active layer 218 is a light-emitting layer disposed on the second active layer 215, may include a phosphide or nitride semiconductor such as (Al, Ga, In)P or (Al, Ga, In)N, and may be grown on the second carrier barrier layer 216 using a technique such as MOCVD, MBE, HVPE, or the like.

In addition, the third active layer 218 may include a quantum well structure (QW) including at least two barrier layers and at least one well layer, and moreover, may include a multi quantum well structure (MQW) including a plurality of barrier layers and a plurality of well layers. A wavelength of light emitted from the third active layer 218 may be adjusted by controlling a composition ratio of materials forming the well layer. In this case, the well layers may include a same element in common, for example, In.

An indium composition of the third active layer 218 may be different from those of the first active layer 212 and the second active layer 215. A peak wavelength of light emitted from the third active layer 218 may be different from those of light emitted from the first active layer 212 and the second active layer 215.

For example, the third active layer 218 may be an active layer that emits light having the peak wavelength within a red wavelength range. Alternatively, a number of pairs of the barrier layers and the well layers in the third active layer 218 may be 6 or less. The number of pairs of the barrier layers and the well layers in the third active layer 218 may be 4 or less. Alternatively, the number of pairs of the barrier layers and the well layers in the third active layer 218 may be 3 or less. A well layer thickness of the third active layer 218 may be 2 nm to 4 nm. A barrier layer thickness of the third active layer 218 may be larger than those of the barrier layers of the first and second active layers 212 and 215. The red light may have a difference between a peak wavelength and a dominant wavelength of 5 to 30 nm. In detail, the third active layer 218 may emit light having the peak wavelength between 620 nm and 640 nm and may have a dominant wavelength between 600 nm and 630 nm. By keeping the difference between the peak wavelength and the dominant wavelength small, the color deviation may be reduced, thereby resulting in more vivid color expression. The peak wavelength of red light may be longer than that of the dominant wavelength. Through this, it is possible to correct for eye sensitivity while increasing the light energy, thereby reducing the design difficulty.

However, this is exemplary, and it is obvious that an example in which the first active layer 212 emits red light and the third active layer 218 emits blue light is also possible.

The second conductivity type semiconductor layer 219 is a semiconductor layer disposed on the third active layer 218 and various configurations are possible. The second conductivity type semiconductor layer 219 may include a phosphide or nitride semiconductor such as (Al, Ga, In)P or (Al, Ga, In)N. The second conductivity type semiconductor layer 219 may be doped with a conductivity type opposite to that of the first conductivity type semiconductor layer 203. For example, the second conductivity type semiconductor layer 219 may be doped as a p-type by including an impurity such as Mg.

The first light-emitting region 210 may have a light-exiting surface formed on a side of the first conductivity type semiconductor layer 203 or the second conductivity type semiconductor layer 219 through which light is emitted. For example, light generated in the first through third active layers 212, 215, and 218 may be emitted to the outside through the first conductivity type semiconductor layer 203, or may be emitted to the outside through the second conductivity type semiconductor layer 219. A concave-convex structure may be formed on one surface of the first conductivity type semiconductor layer 203 or one surface of the second conductivity type semiconductor layer 219 so as to increase light extraction efficiency.

The first light-emitting region 210 may include three first through third active layers 212, 215, and 218 between the first conductivity type semiconductor layer 203 and the second conductivity type semiconductor layer 219. The first through third active layers 212, 215, and 218 may emit light when power is applied to the first light-emitting region 210. The first through third active layers 212, 215, and 218 may emit light having a peak wavelength different from one another, respectively. For example, the first active layer 212 may emit light in a blue wavelength band, the second active layer 215 may emit light in a green wavelength band, and the third active layer 218 may emit light in a red wavelength band. As another example, the first active layer 212 may emit light in the red wavelength band, the second active layer 215 may emit light in the green wavelength band, and the third active layer 218 may emit light in the blue wavelength band.

Meanwhile, the first through third active layers 212, 215, and 218 may include a same group V material. Alternatively, the first through third active layers 212, 215, and 218 may include a same group III material. In this case, contents of the group V material or group III material of each of the first through third active layers 212, 215, and 218 may be different from one another.

A band gap may increase from the first active layer 212 to the third active layer 218. Alternatively, the first through third active layers 212, 215, and 218 may be sequentially disposed such that the band gap increases toward an exiting direction of light (a direction toward the substrate 201 or direction toward the second conductivity type semiconductor layer 218). Alternatively, the first through third active layers 212, 215, and 218 may be disposed vertically such that a wavelength of light emitted therefrom becomes shorter toward the exiting direction of light (the direction toward the substrate 201 or direction toward the second conductivity type semiconductor layer 219).

The second light-emitting region 220 may be configured to be identical or similar to the first light-emitting region 210. The second light-emitting region 220 is a light-emitting region including the plurality of active layers, and the second light-emitting region 220 may include a first active layer 222 disposed on the first conductivity type semiconductor layer 203, a first carrier barrier layer 223 disposed on the first active layer 222, a second active layer 225 disposed on the first carrier barrier layer 223, a second carrier barrier layer 226 disposed on the second active layer 225, a third active layer 228 disposed on the second carrier barrier layer 226, and a second conductivity type semiconductor layer 229 disposed on the third active layer 228. The second light-emitting region 220 may further include a pre-strain layer 221 between the first conductivity type semiconductor layer 203 and the first active layer 222.

Likewise, the third light-emitting region 230 may be configured to be identical to or similar to the first light-emitting region 210 or the second light-emitting region 220. The third light-emitting region 230 is a light-emitting region including the plurality of active layers, and the third light-emitting region 230 may include a first active layer 232 disposed on the first conductivity type semiconductor layer 203, a first carrier barrier layer 233 disposed on the first active layer 232, a second active layer 235 disposed on the first carrier barrier layer 233, a second carrier barrier layer 236 disposed on the second active layer 235, a third active layer 238 disposed on the second carrier barrier layer 236, and a second conductivity type semiconductor layer 239 disposed on the third active layer 238. The third light-emitting region 230 may further include a pre-strain layer 231 between the first conductivity type semiconductor layer 203 and the first active layer 232.

The first through third light-emitting regions 210, 220, and 230 may be spaced apart from one another on one surface of the substrate 201 at an interval. The first through third light-emitting regions 210, 220, and 230 may be separated into individual light-emitting regions by etching some of layers sequentially stacked on the substrate 201. A width of the interval may vary depending on a distance from the substrate 201. For example, the width of the interval may increase as it is farther from the substrate 201.

Accordingly, the first through third active layers 212, 215, and 218 of the first light-emitting region 210 may be configured to be identical or similar to the first through third active layers 222, 225, 228, 232, 235, and 238 of corresponding second or third light-emitting region 220 or 230, respectively. A deviation between a well layer indium content in the first through third active layers 212, 215, and 218 of the first light-emitting region 210 and a well layer indium content in the first through third active layers 222, 225, 228, 232, 235, and 238 of the second and third light-emitting regions 220 and 230 may be within 10%.

The light emitting module 200 may further include an insulation layer 260 covering the first light-emitting region through the third light-emitting regions 210, 220, and 230.

In addition, the light emitting module 200 may further include a reflection layer 270 disposed in a space between the first through third light-emitting regions 210, 220, and 230. The reflection layer 270 is disposed between adjacent light-emitting regions 210, 220, and 230 and may reflect light directed toward side directions of the light-emitting regions 210, 220, and 230 toward a light exiting surface, thereby increasing light extraction efficiency. In a case that the reflection layer 270 fills the space between the first through third light-emitting regions 210, 220, and 230, each of the light-emitting regions 210, 220, and 230 may be securely supported.

The reflection layer 270 may be formed of various materials such as metal, polymer, epoxy, silicon, inorganic material, TiO₂, or others. In addition, the reflection layer 270 may further include a filler for light reflection or light absorption.

The light emitting module 200 may include a first electrode 240 and a second electrode 250 that are electrically connected to the first light-emitting region 210.

The first electrode 240 may be connected to the first conductivity type semiconductor layer 203 of the first light-emitting region 210. The first electrode 240 may be connected to the first conductivity type semiconductor layer 203 of the first light-emitting region 210 exposed through an opening of the insulation layer 260.

The second electrode 250 may be connected to the second conductivity type semiconductor layer 219 of the first light-emitting region 210. The second electrode 250 may be connected to the second conductivity type semiconductor layer 219 exposed through an opening of the insulation layer 260. The second electrode 250 may contact one surface of the second conductivity type semiconductor layer 219.

In this case, a transparent electrode 251 may be disposed on one surface of the second conductivity type semiconductor layer 219. The transparent electrode 251 is exposed through an opening of the insulation layer 260 and the second electrode 250 may be disposed on an exposed region. It is obvious that the transparent electrode 251 may be omitted as an optional configuration.

Similarly, the light emitting module 200 may include the first electrode 240 and the second electrode 250 electrically connected to the second light-emitting region 220 and the third light-emitting region 230.

The second electrode 250 may be configured as individual electrodes for the first through third light-emitting regions 210, 220, and 230. That is, the second electrode 250 may be a second individual electrode connected to the second conductivity type semiconductor layers 219, 229, and 239 of each of the light-emitting regions 210, 220, and 230, respectively.

The first electrode 240 may be configured as a common electrode for the first through third light-emitting regions 210, 220, and 230. In this case, the first electrodes 240 may be electrically connected to one another. However, the present invention is not limited thereto, and it is obvious that an example in which the first electrodes 240 are configured as individual electrodes for each of the light-emitting regions 210, 220, and 230 is also possible.

When power is applied to the first light-emitting region 210 through the first and second electrodes 240 and 250, a current path is formed in the first light-emitting region 210, so that light may be emitted from the first through third active layers 212, 215, and 218. In this case, a dominant wavelength of light emitted from the first light-emitting region 210 may be determined by a current applied thereto, that is, a current value or current density.

For example, as the current value or current density applied to the first light-emitting region 210 increases, light emitted therefrom may be varied from the red wavelength band→the green wavelength band→white light→the blue wavelength band.

Similarly, when power is applied to the second light-emitting region 220 through the first and second electrodes 240 and 250, a current path is formed in the second light-emitting region 220, so that light may be emitted from the first through third active layers 222, 225, and 228. In this case, a dominant wavelength of light emitted from the second light-emitting region 220 may be determined by a current applied thereto, that is, a current value or current density.

For example, as the current value or current density applied to the second light-emitting region 220 increases, light emitted therefrom may be varied from the red wavelength band→the green wavelength band→white light→the blue wavelength band.

Likewise, when power is applied to the third light-emitting region 230 through the first and second electrodes 240 and 250, a current path is formed in the third light-emitting region 230, so that light may be emitted from the first through third active layers 232, 235, and 238. In this case, a dominant wavelength of light emitted from the third light-emitting region 230 may be determined by a current applied thereto, that is, a current value or current density.

For example, as the current value or current density applied to the third light-emitting region 230 increases, light emitted therefrom may be varied from the red wavelength band→the green wavelength band→white light→the blue wavelength band.

Accordingly, by controlling the current value and the current density applied to each of the first through third light-emitting regions 210, 220, and 230, a color temperature and wavelength band of light emitted from each of the light-emitting regions 210, 220, and 230 may be adjusted differently.

The first through third light-emitting regions 210, 220, and 230 may implement light-emitting regions of various colors including three primary colors, by a simple manner of vertically and continuously stacking and etching the first conductivity type semiconductor layer 203, the plurality of active layers 212, 215, 218, 222, 225, 228, 232, 235, and 238 that emit light of different peak wavelengths, and the second conductivity type semiconductor layers 219, 229, and 239 on the substrate 201. Accordingly, there is no need to transfer individually grown light emitting portions onto the substrate, thereby simplifying a process. In addition, since there is no need for an adhesive layer between the vertically stacked active layers 212, 215, 218, 222, 225, 228, 232, 235, and 238, the process may be simplified, and failure or damage caused by deformation or peeling of the adhesive layer due to heat may be prevented.

In addition, it is possible to increase an amount of light by securing large light-emitting areas through which light is emitted from the first through third light-emitting regions 210, 220, and 230. In detail, even when one light-emitting region 210, 220, or 230 includes the plurality of stacked active layers, an area of a semiconductor layer that needs to be removed so as to apply power to the light-emitting regions 210, 220, and 230 may be minimized. As a result, the light emitting areas of the light-emitting regions 210, 220, and 230 may be maximized.

In addition, since the first through third light-emitting regions 210, 220, and 230 include the plurality of active layers, the luminous intensity of light emitted from each of the light-emitting regions 210, 220, and 230 may be adjusted and a wavelength may be finely adjusted through current control accordingly, thereby increasing color accuracy and clarity, improving efficiency, extending lifespan, and optimizing visibility.

Meanwhile, areas of regions where light is emitted from the first light-emitting region 210 through the third light-emitting region 230 may be same or different from one another. Light exiting areas in the first light-emitting region 210 through the third light-emitting region 230 may be different depending on the wavelength of light emitted from each of the light-emitting regions 210, 220, and 230. For example, a light exiting area of light-emitting region 210, 220, or 230 that emits light of a wavelength requiring a large amount of light may be made larger than that of another light-emitting region 210, 220, or 230.

In addition, in a case of FIG. 4, the light emitting module 200 is exemplarily illustrated as including three light-emitting regions 210, 220, and 230 by including each one of the first through third light-emitting regions 210, 220, and 230, but each of the light-emitting regions 210, 220, and 230 may be provided in a plurality. For example, the light-emitting region 210, 220, or 230 that emits light of a wavelength requiring a large amount of light may include a number thereof greater than that of another light-emitting region 210, 220, or 230.

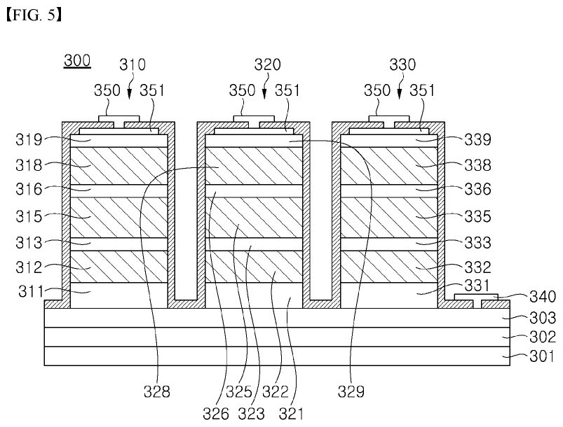

FIG. 5 illustrates a light emitting module 300 according to a third embodiment of the present invention. Hereinafter, the light emitting module 300 will be described in detail, focusing on differences from the light emitting modules 100 and 200 according to the first and second embodiments.

The reflection layer 270 of FIG. 4 is omitted in the light emitting module 300, and a first electrode 340 may be configured as a first common electrode for first through third light-emitting regions 310, 320, and 330.

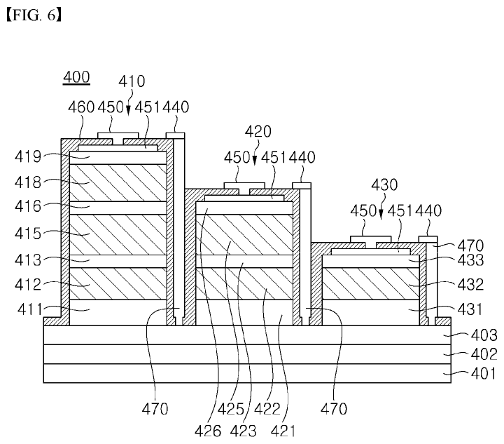

FIG. 6 illustrates a light emitting module 400 according to a fourth embodiment of the present invention. Hereinafter, the light emitting module 400 will be described in detail, focusing on differences from the light emitting modules 100, 200, and 300 according to the first through third embodiments.

The light emitting modules 200 and 300 according to the second and third embodiments are configured such that the numbers of active layers included in each of the light-emitting regions 210, 220, 230, 310, 320, and 330 are the same, but in a case of the light emitting module 400 according to the fourth embodiment, a number of active layers included in each of light-emitting regions 410, 420, and 430 may be different from one another. That is, a number of active layers in at least one of the light-emitting regions 410, 420, and 430 may be different from those of active layers in the other light-emitting regions 410, 420, and 430.

For example, the first light-emitting region 410 includes three vertically stacked active layers 412, 415, and 418, but the second and third light-emitting regions 420 and 430 may include different numbers of active layers. In detail, the second light-emitting region 420 may include two vertically stacked active layers 422 and 425, and the third light-emitting region 430 may include a single active layer 432.

In a case that the first light-emitting region 410 includes three active layers 412, 415, and 418 of RGB, as a current value or current density applied thereto increases, light emitted therefrom may be varied from a red wavelength band→a green wavelength band→white light→a blue wavelength band. In a case that the second light-emitting region 420 includes two active layers 422 and 425 of GB, as a current value or current density applied thereto increases, light emitted therefrom may be varied from the green wavelength band→white light→the blue wavelength band.

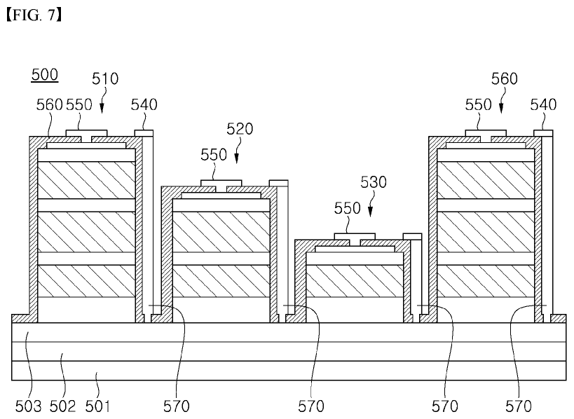

FIG. 7 illustrates a light emitting module 500 according to a fifth embodiment of the present invention. Hereinafter, the light emitting module 400 will be described in detail, focusing on differences from the light emitting modules 100, 200, 300, and 400 according to the first through fourth embodiments.

The light emitting module 500 may include first through fourth light-emitting regions 510, 520, 530, and 560. The fourth light-emitting region 560 may be configured to be identical or similar to the first light-emitting region 510. The fourth light-emitting region 560, in a case that the light amount of the first light-emitting region 510 is insufficient, may compensate therefor, and may play a role in substantially increasing a light-emitting area of light emitted from the first light-emitting region 510.

Although the present disclosure has been described above with reference to preferred embodiments, it will be understood by those skilled in the art or having ordinary knowledge in the art that various modifications and changes may be made to the present disclosure without departing from the spirit and technical scope of the present disclosure as set forth in the claims below.

Therefore, the technical scope of the present disclosure should not be limited to the contents described in the detailed description of the specification, but should be defined by the scope of the patent claims.

### DESCRIPTION OF REFERENCE NUMERALS

100, 200, 300, 400, 500: Light emitting module
110, 120, 130, 210, 220, 230, 310, 320, 330, 410, 420, 430, 510, 520, 530, 560: Light-emitting region
101, 201, 301, 401, 501: Substrate
202, 302, 402, 502: Buffer layer
111, 203, 303, 403, 503: First conductivity type semiconductor layer
112, 115, 118, 122, 125, 128, 132, 135, 138, 212, 215, 218, 222, 225, 228, 232, 235, 238, 312, 315, 318, 322, 325, 328, 332, 335, 338, 412, 415, 418, 422, 425, 428, 432, 435, 438: Active layer
119, 219, 229, 239, 319, 329, 339, 419, 429, 439: Second conductivity type semiconductor layer
140, 240, 340, 440, 540: First electrode
150, 250, 350, 450, 550: Second electrode
160, 260, 360, 460, 560: Insulation layer
170: Connection electrode portion
270, 470, 570: Reflection layer

1. A light emitting module, comprising:
a substrate; and
a plurality of light-emitting regions disposed on one surface of the substrate,
wherein at least one of the plurality of light-emitting regions includes a non light-emitting active layer disposed so as to deviate from a current path when power is applied.

2. The light emitting module of claim 1,
wherein the non light-emitting active layer is provided in a plurality.

3. The light emitting module of claim 1,
wherein each of the plurality of light-emitting regions includes an active layer that emits light when power is applied.

4. The light emitting module of claim 1,
wherein one of the plurality of light-emitting regions is a first light-emitting region including a first non-light emitting active layer, a second non-light emitting active layer disposed over the first non-light emitting active layer, and a first active layer disposed over the second non-light emitting active layer and emitting a first light when current is applied.

5. The light emitting module of claim 4,
wherein another of the plurality of light-emitting regions is a second light-emitting region including a first non-light emitting active layer and a second active layer disposed over the first non-light emitting active layer and emitting a second light when current is applied.

6. The light emitting module of claim 5,
wherein another of the plurality of light-emitting regions is a third light-emitting region including a third active layer disposed over the substrate and emitting a third light when current is applied.

7. The light emitting module of claim 6,
wherein heights from an upper surface of the substrate to the first, second, and third active layers are different from one another.

8. The light emitting module of claim 6,
wherein the first, second, and third lights emitted from the first, second, and third active layers have peak wavelengths different from one another.

9. The light emitting module of claim 6, wherein:
each of the first, second, and third light-emitting regions includes a second electrode disposed over the first, second, and third active layers, respectively, and
heights from an upper surface of the substrate to the second electrode for each of the first, second, and third light-emitting regions are different from one another.

10. A light emitting module, comprising:
a substrate; and
a plurality of light-emitting regions disposed on one surface of the substrate, wherein:
the plurality of light-emitting regions include a plurality of active layers, and
power applied to the plurality of light-emitting regions is independently controlled.

11. The light emitting module of claim 10,
wherein a number of the active layers included in each of the plurality of light-emitting regions is the same.

12. The light emitting module of claim 10,
wherein a dominant wavelength of light emitted from each of the plurality of light-emitting regions is varied depending on a current applied to the each of the plurality of light-emitting regions.

13. The light emitting module of claim 10,
wherein each of the plurality of light-emitting regions includes a first active layer disposed on a first conductivity type semiconductor layer, a first carrier barrier layer disposed on the first active layer, a second active layer disposed on the first carrier barrier layer, a second carrier barrier layer disposed on the second active layer, a third active layer disposed on the second carrier barrier layer, and a second conductivity type semiconductor layer disposed on the third active layer.

14. The light emitting module of claim 13,
wherein the first, second, and third active layers respectively emit light having a peak wavelength different from one another.

15. The light emitting module of claim 13,
wherein a band gap decreases from the first active layer to the third active layer.

16. The light emitting module of claim 13,
wherein a thickness of a barrier layer of the third active layer is larger than respective thicknesses of barrier layers of the first active layer and the second active layer.

17. The light emitting module of claim 13, wherein:
each of the first, second, and third active layers includes a multi quantum well structure in which barrier layers and well layers are sequentially stacked, and
a number of pairs of the multi quantum well structure of the first active layer is greater than a number of pairs of the multi quantum well structure in the second and third active layers.

18. The light emitting module of claim 13,
wherein doping concentrations of the first and second carrier barrier layers are lower than a doping concentration of the first conductivity type semiconductor layer.

19. The light emitting module of claim 13, wherein:
the first, second, and third active layers include a multi quantum well structure in which barrier layers and well layers are sequentially stacked, and
the first and second carrier barrier layers have a band gap higher than a band gap of an adjacent barrier layer.

20. A light emitting module, comprising:
a substrate; and
a plurality of light-emitting regions disposed on one surface of the substrate;
a first common electrode commonly connected to the plurality of light-emitting regions; and
a plurality of second individual electrodes connected to the plurality of light-emitting regions, respectively, wherein:
at least one of the plurality of light-emitting regions includes a plurality of active layers, and
power applied to the plurality of light-emitting regions is independently controlled.
